(19) United States
(12) Patent Application Publication
(10) Pub. No.: US 2005/0258501 A1
(43) Pub. Date: Nov. 24, 2005

(54) Light receiving element, method for producing the same, and light receiving element with built-in circuit

(75) Inventors: Kazuhiro Natsuaki, Sakurai-shi (JP); Toshihiko Fukushima, Nara-shi (JP)

Correspondence Address: NIXON & VANDERHYE, PC, 901 NORTH GLEBE ROAD, 11TH FLOOR, ARLINGTON, VA, 22203, US

(73) Assignee: SHARP KABUSHIKI KAISHA, Osaka-shi (JP)

(21) Appl. No.: 10/637,512

(22) Filed: Aug. 11, 2003

(30) Foreign Application Priority Data
Aug. 28, 2002 (JP) 2002-249641

(51) Int. Cl. H01L 27/14

(52) U.S. Cl. 257/414

(57) ABSTRACT

A light receiving element includes a substrate; and an epitaxial layer provided on the substrate and containing an impurity diffusion layer extending from a surface of the epitaxial layer to a prescribed depth. The prescribed depth is about 0.3 μm or less. The impurity diffusion layer contains an impurity at a concentration of less than about 1×10²⁰ cm⁻³.

### BACKGROUND OF THE INVENTION

1. Field of the Invention

The present invention relates to a light receiving element, a method for producing the same, and a light receiving element with a built-in circuit.

2. Description of the Related Art

Photodiodes are known as one type of light receiving elements. Photodiodes have an opto-electronic conversion function for converting an optical signal into an electric signal, and are widely used for optical pickups, optical spatial transmission devices and the like.

Photodiodes perform opto-electronic conversion as follows.

An inverse bias voltage is applied to a PN junction formed in a semiconductor layer in a photodiode, and a depletion layer formed by the application of the inverse bias voltage and the vicinity of the depleted layer is irradiated with light. Thus, carriers (optical carriers) are generated in the semiconductor layer. The optical carriers move in accordance with the potential gradient (built-in electric field) generated in a diffusion layer to reach the depletion layer, where an optical activating force (optical current) is generated.

Recently, demand for optical recording mediums such as CDs (compact discs), DVDs (digital versatile discs) and the like has increased. To satisfy the demand, photodiodes used for optical pickups, included in optical disc apparatuses for recording information to and/or reproducing information from an optical recording medium, are under active research.

Generally, the recording density of an optical recording medium can be increased as the oscillation wavelength of a semiconductor laser device used as a light source is shortened. The oscillation wavelength of the semiconductor laser device used for an optical pickup is 780 nm in the case where the optical recording medium is a CD, and is 650 nm in the case where the optical recording medium is a DVD. As the recording density of the optical recording medium increases, a semiconductor laser device having a shorter oscillation wavelength is required. It is expected that a semiconductor laser device for emitting light having a wavelength of about 405 nm will be required in the future. The oscillation wavelength of the semiconductor laser device required is considered to have to become shorter and shorter.

As the oscillation wavelength of the semiconductor laser device used as the light source is shortened, the light absorption coefficient in the semiconductor layer of the photodiode is increased. For example, the light absorption coefficient of silicon is 2500 cm⁻¹ for light having a wavelength of 650 nm, and is 30000 cm⁻¹ for light having a wavelength of 410 nm. The light absorption coefficient of silicon is 10 times or more higher for the light having a wavelength of 410 nm than for the light having a wavelength of 650 nm.

The thickness of the semiconductor layer (depth from the surface of the semiconductor layer), at which the intensity of light entering the inside of the semiconductor layer is 10% of the intensity of light at the surface of the semiconductor layer, is reduced as the oscillation wavelength is shortened. In the case of silicon, such a thickness is 9.2 μm for light having a wavelength of 650 nm, and is 0.76 μm for light having a wavelength of 410 nm. The thickness is 1/10 or less for the light having a wavelength of 410 nm than for the light having a wavelength of 650 nm.

Thus, as the oscillation wavelength of the light emitted by the semiconductor laser device is shortened, the light absorption coefficient of the photodiode is increased.

Accordingly, when the oscillation wavelength of the semiconductor laser device is shortened, the number of electron-hole pairs (optical carriers) generated in the vicinity of the surface of the semiconductor layer of the photodiode is increased. It is expected that this will result in the behavior of the optical carriers in the vicinity of the surface of the semiconductor layer greatly influencing the sensitivity and response speed of the photodiode. For example, the impurity concentration and the impurity concentration profile in the vicinity of the surface of a light receiving section of the photodiode for receiving light are considered to greatly influence the light receiving sensitivity of the photodiode.

Photodiodes have been demanded to have a greater response speed. For raising the response speed of the photodiode, the junction capacitance of the photodiode is reduced by using a substrate having a high resistivity of about 100 Ωcm or greater, or a substrate having a high resistivity epitaxial layer of about 100 Ωcm or greater formed thereon. In the following description of this specification, a substrate having a high resistivity of about 100 Ωcm or greater, and a substrate having a high resistivity epitaxial layer of about 100 Ωcm or greater formed thereon will be comprehensively referred to as a “high resistivity substrate”.

For example, Japanese Laid-Open Publication No. 7-240534 discloses a light receiving element using a high resistivity substrate which can deal with light having a short wavelength.

FIG. 8 is a schematic cross-sectional view illustrating a structure of a conventional light receiving element 100 which is disclosed in Japanese Laid-Open Publication No. 7-240534. FIG. 8 shows a part of the light receiving element 100 for the sake of simplicity.

The light receiving element 100 includes an n⁻ semiconductor substrate 103 having a high resistivity (hereinafter, referred to as an n⁻ high resistivity semiconductor substrate 103) containing silicon, and a p⁺ impurity diffusion region 105 formed by diffusing a p-type impurity with a peak concentration of 1×10²⁰ cm⁻³ to a depth of about 0.1 μm or less from a surface of the n⁻ high resistivity semiconductor substrate 103. Hereinafter, the p⁺ impurity diffusion region 105 will be referred to as a “light receiving section diffusion layer”. The light receiving section diffusion layer 105 is an epitaxial layer.

The light receiving section diffusion layer 105 is used as an anode. An oxide layer 106 is formed on the light receiving section diffusion layer 105. The light receiving section diffusion layer 105 is connected to an anode electrode 107a formed of a metal layer via an opening formed in the oxide layer 106.

An anode electrode formation region 105a in the light receiving section diffusion layer 105 is formed to be deeper than a light receiving section (a central area of the light receiving section diffusion layer 105 on which no electrode is formed). Owing to such a structure, the resistance of the light receiving element 100 is reduced. The light receiving element 100 is structured such that the peak concentration position of the p-type impurity in the light receiving section diffusion layer 105 is as close as possible to the surface of the light receiving section diffusion layer 105.

n⁺ impurity diffusion regions (cathode diffusion layers) 104 used as cathodes are formed so as to surround the light receiving section diffusion layer 105.

Each n⁺ impurity diffusion region 104 is connected to a cathode electrode 107b formed of a metal layer via an opening formed in the oxide layer 106.

A bottom N⁺ diffusion layer 102 and a bottom oxide layer 101 are formed on a bottom surface of the n⁻ semiconductor substrate 103 in this order.

In the light receiving element 100, a prescribed voltage is applied between the cathode electrode 107b formed on the cathode diffusion layer 104 and the anode electrode 107a formed on the light receiving section diffusion layer 105. Thus, an inverse bias voltage is applied to the PN junction between the light receiving section diffusion layer 105 and the n⁻ semiconductor substrate 103.

FIG. 9 is a graph schematically illustrating an impurity concentration profile of the light receiving section diffusion layer 105 and the n⁻ high resistivity semiconductor substrate 103 at the cross-section taken along line X′-Y′ of FIG. 8.

In FIG. 9, the vertical axis represents the impurity concentration in silicon, and the horizontal axis represents the depth from the surface of the photodiode (i.e., from the surface of the light receiving section diffusion layer 105).

As shown in FIG. 9, the n⁻ high resistivity semiconductor substrate 103 has a low impurity concentration. Therefore, when an inverse bias voltage is applied, a depletion layer extending widely from the junction between the light receiving section diffusion layer 105 and the n⁻ high resistivity semiconductor substrate 103 toward the n⁻ high resistivity semiconductor substrate 103 is formed. Thus, the junction capacitance of the photodiode is reduced, which realizes a high speed response.

In this case, when the wavelength of light received by the light receiving element 100 is shortened and thus the amount of light absorbed in the vicinity of a surface of the light receiving element 100 is increased, the number of optical carriers generated in the light receiving section diffusion layer 105 is increased to cause recombination in the vicinity of the surface of the light receiving section diffusion layer 105, and thus the quantum efficiency of the light receiving element 100 is lowered. In the light receiving element 100, however, the light receiving section diffusion layer 105 is formed to be as shallow as about 0.1 μm or less in order to prevent the quantum efficiency from being lowered. Owing to such a structure, the number of optical carriers generated in the light receiving section diffusion layer 105 is decreased and the number of the optical carriers generated at a level deeper than the light receiving section diffusion layer 105 is increased. Therefore, a larger number of optical carriers reach the depletion layer. Thus, the light receiving element 100 obtains an improved sensitivity.

In addition, since the light receiving section diffusion layer 105 is shallow as described above, the impurity concentration profile can be made steep as shown in FIG. 9, resulting in the potential gradient being steep. When this occurs, the speed at which the optical carriers move to the depletion layer can be improved. Therefore, the optical carriers can reach the depletion layer before recombination occurs. Thus, the light receiving element 100 obtains an improved sensitivity.

In the state where the peak concentration position of the impurity is inside the light receiving section diffusion layer 105, instead of at the surface of the light receiving section diffusion layer 105, the optical carriers generated in the vicinity of the surface move toward the surface in accordance with the concentration distribution of the impurity in the light receiving section diffusion layer 105. This promotes recombination at the surface. In order to prevent the optical carriers from moving toward the surface, the light receiving element 100 is structured such that the peak concentration position of the impurity is at a position as close as possible to the surface of the light receiving section diffusion layer 105 as shown in FIG. 9. In this manner, recombination at the surface is suppressed, and the light receiving element 100 obtains an improved sensitivity.

Recently, as described above, a higher density and a higher response speed have been demanded for optical recording mediums. In compliance with the demands, the wavelength of the light emitted by the semiconductor laser device used as a light source is being made shorter and shorter.

However, as the wavelength of light is shortened, the sensitivity of the light receiving element is lowered. For example, the opto-electronic conversion efficiency of silicon is theoretically 0.629 A/W for light having a wavelength λ=780 nm, is 0.524 A/W for light having a wavelength λ=650 nm, and is 0.327 A/W for light having a wavelength λ=405 nm.

Accordingly, with the amount of light received by the light receiving element being the same, when the wavelength of the light is shorter, the magnitude of the obtained current is smaller. This lowers the S/N ratio of the circuit. Under the circumstances, it is desired to raise the quantum efficiency to as close as possible to 100%. Especially in an optical disc apparatus using a blue laser, it is strongly demanded to raise the quantum efficiency to almost 100% for the wavelength of 405 nm to realize a high sensitivity.

In the light receiving element 100 described in Japanese Laid-Open Publication No. 7-240534, the light receiving section diffusion layer is formed to be as shallow as about 0.1 μm or less, so that the number of optical carriers generated in the light receiving section diffusion layer is decreased and the light receiving sensitivity is improved. The position of a peak impurity concentration is as close as possible to the surface of the light receiving section diffusion layer, so that recombination at the surface is suppressed and the light receiving sensitivity is improved. The “peak impurity concentration” indicates the peak of the impurity concentration of an impurity diffusion layer. The “impurity diffusion layer” is formed by diffusing an impurity.

When the recording density of an optical recording medium is increased, a higher data reading speed, and thus a higher response speed of the light receiving element, are demanded. The response speed of the light receiving element fc is generally represented by:
fc(−3 dB)=1/(2πRC),
where R represents a series resistance of a light receiving element such as a cathode resistance, an anode resistance and the like; and C represents a capacitance of the light receiving element. As can be appreciated from the above expression, the response speed of the light receiving element is increased as the series resistance and the capacitance of the light receiving element are decreased.

In the light receiving element 100 described in Japanese Laid-Open Publication No. 7-240534, an n⁻ high resistivity semiconductor substrate is used, so that the capacitance of the light receiving element is sufficiently lowered. However, the light receiving section diffusion layer 105, which is as shallow as about 0.1 μm or less, has a high resistance. In order to lower the series resistance of the light receiving element to realize a higher response speed, it is desirable to form the light receiving section diffusion layer 105 to be deeper than about 0.1 μm while avoiding lowering the quantum efficiency.

It is demanded to provide a light receiving element having a higher response speed at a lower resistance owing to a light receiving section diffusion layer in an epitaxial layer being formed to a level sufficiently deep from a surface thereof, and also having an improved sensitivity for light having a wavelength as short as, for example, 405 nm.

### SUMMARY OF THE INVENTION

According to one aspect of the invention, a light receiving element includes a substrate; and an epitaxial layer provided on the substrate and containing an impurity diffusion layer extending from a surface of the epitaxial layer to a prescribed depth. The prescribed depth is about 0.3 μm or less. The impurity diffusion layer contains an impurity at a concentration of less than about 1×10²⁰ cm⁻³.

In one embodiment of the invention, the substrate is of a first conductivity type, and the impurity is of a second conductivity type.

In one embodiment of the invention, the epitaxial layer is of the first conductivity type.

In one embodiment of the invention, the epitaxial layer is of the second conductivity type.

In one embodiment of the invention, the impurity diffusion layer has a peak impurity concentration of about 1×10¹⁷ cm⁻³ or greater but less than about 1×10²⁰ cm⁻³.

In one embodiment of the invention, the prescribed depth is greater than about 0.1 μm but about 0.3 μm or less.

In one embodiment of the invention, the impurity diffusion layer has a concentration which increases toward the surface of the epitaxial layer.

In one embodiment of the invention, the impurity is arsenic.

In one embodiment of the invention, the first conductivity type is p-type, and the second conductivity type is n-type.

In one embodiment of the invention, the light receiving element further includes a reflection prevention layer including an oxide layer and an Si₃N₄ layer and provided on a surface of the epitaxial layer.

In one embodiment of the invention, the epitaxial layer is a high resistivity layer having a resistivity of about 100 Ωcm or greater.

In one embodiment of the invention, the light receiving element further includes a high resistivity layer having a resistivity of about 100 Ωcm or greater provided between the substrate and the epitaxial layer.

In one embodiment of the invention, the light receiving element performs opto-electronic conversion of light having a wavelength of about 390 nm or longer but about 420 nm or shorter.

According to another aspect of the invention, a method for producing a light receiving element includes the steps of forming an epitaxial layer on a substrate; and implanting an impurity into the epitaxial layer to a prescribed depth, thereby forming an impurity diffusion layer. The prescribed depth is about 0.3 μm or less. The impurity diffusion layer contains the impurity at a concentration of less than about 1×10²⁰ cm⁻³.

In one embodiment of the invention, the step of forming the impurity diffusion layer includes the step of ion-implanting the impurity via an oxide layer formed on a surface of the epitaxial layer.

According to still another aspect of the invention, a light receiving element with a built-in circuit includes a light receiving element, including a substrate; and an epitaxial layer provided on the substrate and containing an impurity diffusion layer extending from a surface of the epitaxial layer to a prescribed depth, wherein the prescribed depth is about 0.3 μm or less, and the impurity diffusion layer contains an impurity at a concentration of less than about 1×10²⁰ cm⁻³; and a circuit element provided on the substrate.

According to still another aspect of the invention, a light receiving element includes a substrate; and an epitaxial layer provided on the substrate and containing an impurity diffusion layer extending from a surface of the epitaxial layer to a prescribed depth. The prescribed depth is greater than about 0.3 μm but about 1.2 μm or less. The impurity diffusion layer contains an impurity at a concentration of less than about 1×10¹⁹ cm⁻³.

In one embodiment of the invention, the substrate is of a first conductivity type, and the impurity is of a second conductivity type.

In one embodiment of the invention, the epitaxial layer is of the first conductivity type.

In one embodiment of the invention, the epitaxial layer is of the second conductivity type.

In one embodiment of the invention, the impurity diffusion layer has a peak impurity concentration of about 1×10¹⁷ cm⁻³ or greater but less than about 1×10¹⁹ cm⁻³.

In one embodiment of the invention, the impurity diffusion layer has a concentration which increases toward the surface of the epitaxial layer.

In one embodiment of the invention, the impurity is arsenic.

In one embodiment of the invention, the first conductivity type is p-type, and the second conductivity type is n-type.

In one embodiment of the invention, the light receiving element further includes a reflection prevention layer including an oxide layer and an Si₃N₄ layer and provided on a surface of the epitaxial layer.

In one embodiment of the invention, the epitaxial layer is a high resistivity layer having a resistivity of about 100 Ωcm or greater.

In one embodiment of the invention, the light receiving element further includes a high resistivity layer having a resistivity of about 100 Ωcm or greater provided between the substrate and the epitaxial layer.

In one embodiment of the invention, the light receiving element performs opto-electronic conversion of light having a wavelength of about 390 nm or longer but about 420 nm or shorter.

According to still another aspect of the invention, a method for producing a light receiving element includes the steps of forming an epitaxial layer on a substrate; and implanting an impurity into the epitaxial layer to a prescribed depth, thereby forming an impurity diffusion layer. The prescribed depth is greater than about 0.3 μm but about 1.2 μm or less. The impurity diffusion layer contains the impurity at a concentration of less than about 1×10¹⁹ cm⁻³.

In one embodiment of the invention, the step of forming the impurity diffusion layer includes the step of ion-implanting the impurity via an oxide layer formed on a surface of the epitaxial layer.

According to still another aspect of the invention, a light receiving element with a built-in circuit includes a light receiving element, including a substrate; and an epitaxial layer provided on the substrate and containing an impurity diffusion layer extending from a surface of the epitaxial layer to a prescribed depth, wherein the prescribed depth is greater than about 0.3 μm but about 1.2 μm or less, and the impurity diffusion layer contains an impurity at a concentration of less than about 1×10¹⁹ cm⁻³; and a circuit element provided on the substrate.

In a light receiving element including an epitaxial layer on a substrate and an impurity diffusion layer extending from a surface of the epitaxial layer to a prescribed depth, the optical carriers generated in the impurity diffusion layer move to the depletion layer by the potential gradient which is caused by the impurity concentration gradient of the impurity diffusion layer. Thus, the optical current is generated. When the impurity diffusion layer has a high impurity concentration, the lifetime of the optical carriers is shortened; namely, the optical carriers are recombined and extinguished before reaching the depletion layer. Such optical carriers cannot contribute to the optical current and thus the sensitivity (quantum efficiency) of the light receiving element is lowered.

As the wavelength of light received by the light receiving element is shortened (for example, to about 390 nm to about 420 nm), the light absorption coefficient in the semiconductor layer of the light receiving element is increased, resulting in the light penetrating the semiconductor layer only to a lesser distance from the surface of the semiconductor layer. This increases the number of optical carriers in the impurity diffusion layer. Therefore, in the case where the impurity diffusion layer has a high impurity concentration, the quantum efficiency of the light receiving element is significantly lowered.

In order to prevent the recombination of the optical carriers in the impurity diffusion layer and thus to prevent the quantum efficiency from being lowered, the impurity diffusion layer having a high impurity concentration is conventionally formed to be shallow (i.e., to have a depth of about 0.1 μm or less). In this case, the impurity concentration profile, and thus the potential gradient, are made steep, so that the speed of the optical carriers moving to the depletion layer is increased. Thus, the optical carriers can reach the depletion layer without causing recombination. According to this method, however, the impurity diffusion layer is shallow and thus the resistance is high, which raises the series resistance of the photodiode. Thus, the response speed of the light receiving element is low.

According to the present invention, the impurity diffusion layer is formed to be deep so as to reduce the resistance, thus realizing a high speed response. Also according to the present invention, the impurity concentration of the impurity diffusion layer is reduced so as to allow the optical carriers to move to the depletion layer without recombination, extending the lifetime of the optical carriers.

For example, where the impurity diffusion layer is formed from the surface of the epitaxial layer to a depth of greater than about 0.1 μm but about 0.3 μm or less, the impurity concentration of the impurity diffusion layer is made lower than about 1×10²⁰ cm⁻³. Where the impurity diffusion layer is formed from the surface of the epitaxial layer to a depth of greater than about 0.3 μm but about 1.2 μm or less, the impurity concentration of the impurity diffusion layer is made lower than about 1×10¹⁹ cm⁻³. Where the impurity concentration is too low, the response speed is lowered. As such, when a high speed response is required, the peak impurity concentration is preferably about 1×10¹⁷ cm⁻³ or greater.

When the position of the peak impurity concentration is located inside the impurity diffusion layer, not at the surface thereof, the optical carriers generated in the vicinity of the surface move toward the surface of the impurity diffusion layer in accordance with the impurity concentration distribution thereof. Thus, recombination of the optical carriers at the surface is promoted. In order to prevent this, the impurity is preferably distributed in the impurity diffusion layer such that the impurity has a concentration which increases toward the surface. In this case, the recombination of the optical carriers at the surface is suppressed, and thus the sensitivity of the light receiving element can be improved.

The impurity diffusion layer is preferably formed by ion implantation performed via an oxide layer which is formed on the surface of the epitaxial layer. The formation is preferably controlled such that the position of the peak impurity concentration is in the oxide layer. Thus, an impurity concentration profile having an impurity concentration which increases toward the surface of the epitaxial layer can be easily formed.

As the impurity of the impurity diffusion layer, arsenic is preferably used, since arsenic has a low diffusion coefficient and thus the depth of the impurity diffusion layer can be easily controlled. Especially, a light receiving element with a built-in circuit, including the light receiving element and the circuit element on one substrate, is exposed to high temperature by the heat treatment for forming the circuit. It is, therefore, preferable to control the depth of the impurity diffusion layer by use of arsenic which has a low diffusion coefficient.

In the case where a reflection prevention layer formed of an oxide layer and an Si₃N₄ layer is provided on the surface of the epitaxial layer, the sensitivity of the light receiving element can be further improved.

In the case where a high resistivity semiconductor layer having a high resistivity of about 100 Ωcm or greater is provided on a surface of the impurity diffusion layer closer to the substrate, the depletion layer is extended toward the high resistivity layer when an inverse bias voltage is applied. Therefore, the capacitance of the light receiving element is reduced so as to realize a high speed response. The epitaxial layer may be a high resistivity layer.

Thus, the invention described herein makes possible the advantages of providing a light receiving element having a high sensitivity for light of a short wavelength and also having a high response speed, a method for producing the same, and a light receiving element with a built-in circuit.

These and other advantages of the present invention will become apparent to those skilled in the art upon reading and understanding the following detailed description with reference to the accompanying figures.

### BRIEF DESCRIPTION OF THE DRAWINGS

FIG. 1 is a cross-sectional view illustrating a schematic structure of a light receiving element with a built-in circuit according to a first example of the present invention;

FIG. 2 is a graph illustrating an impurity concentration profile for explaining the behavior of optical carriers generated in an n-type impurity diffusion layer of the light receiving element with a built-in circuit shown in FIG. 1;

FIG. 3 is a graph illustrating an impurity concentration profile for explaining the behavior of optical carriers generated in an n-type impurity diffusion layer;

FIG. 4 is a graph illustrating a quantum efficiency with respect to the light of a wavelength of 405 nm which is obtained while the depth of impurity diffusion and the peak impurity concentration are varied;

FIG. 5 is a graph schematically illustrating an impurity concentration profile of the n-type impurity diffusion layer, an n-type epitaxial layer, and a p-type high resistivity epitaxial layer at a cross-section of the light receiving element with a built-in circuit along line X-Y of FIG. 1;

FIGS. 6A through 6D are cross-sectional views illustrating a method for producing the light receiving element with a built-in circuit shown in FIG. 1;

FIG. 7 is a graph schematically illustrating an impurity concentration profile, corresponding to FIG. 5, of a light receiving element with a built-in circuit according to a second example of the present invention;

FIG. 8 is a schematic cross-sectional view illustrating a structure of a conventional light receiving element; and

FIG. 9 is a graph schematically illustrating an impurity concentration profile of a light receiving section diffusion layer and an n⁻ high resistivity semiconductor substrate at a cross-section taken along line X′-Y′ of FIG. 8.

### DESCRIPTION OF THE PREFERRED EMBODIMENTS

Hereinafter, the present invention will be described by way of illustrative examples with reference to the accompanying drawings.

In the following description, a light receiving element with a built-in circuit, which includes a light receiving element and a circuit element on one substrate, will be described as an example. The present invention is not limited to such a light receiving element with a built-in circuit, but encompasses a structure including a light receiving element on a substrate without a circuit element.

### EXAMPLE 1

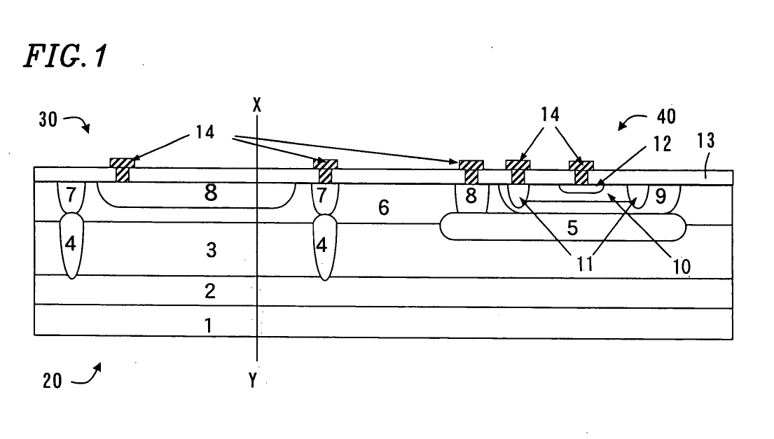

FIG. 1 is a cross-sectional view schematically illustrating a structure of a light receiving element with a built-in circuit 20 according to a first example of the present invention. FIG. 1 shows a part of the a light receiving element with a built-in circuit 20 including one photodiode region and one bipolar transistor element region, for the sake of simplicity.

The light receiving element with a built-in circuit 20 includes a p-type semiconductor substrate 1 formed of silicon or the like and having a resistivity of about 40 Ωcm, a p-type high concentration buried diffusion layer 2, a p-type high resistivity epitaxial layer 3 having a resistivity of about 100 Ωcm or higher, and an n-type epitaxial layer 6 having a resistivity of about 1 Ωcm to 5 Ωcm. The layers 2, 3 and 6 are sequentially stacked on the p-type semiconductor substrate 1 in that order.

The light receiving element with a built-in circuit 20 includes a photodiode region 30 and a bipolar transistor element region 40 adjacent to the photodiode region 30. The photodiode region 30 acts as a light receiving element, and the bipolar transistor element region 40 acts as a circuit element.

The photodiode region 30 and the bipolar transistor element region 40 are isolated from each other by a p-type buried diffusion layer 4 and a p-type separation diffusion layer 7. The p-type buried diffusion layer 4 is provided in the p-type high resistivity epitaxial layer 3 and extends from the interface between the p-type high resistivity epitaxial layer 3 and the p-type high concentration buried diffusion layer 2 to the interface between the p-type high resistivity epitaxial layer 3 and the n-type epitaxial layer 6. The p-type separation diffusion layer 7 is provided in the n-type epitaxial layer 6 and extends from a top surface of the n-type epitaxial layer 6 to the p-type buried diffusion layer 4.

The photodiode region 30 includes an n-type impurity diffusion layer 8 which is formed by diffusing an n-type impurity with a peak concentration of less than about 1×10²⁰ cm⁻³ (for example, about 8×10¹⁹ cm⁻³) to a depth of about 0.3 μm or less (for example, about 0.3 μm) from the surface of the n-type epitaxial layer 6.

The bipolar transistor element region 40 includes an n-type buried diffusion layer 5 which is buried at an interface between the p-type high resistivity epitaxial layer 3 and the n-type epitaxial layer 6. On the n-type buried diffusion layer 5, a bipolar n-type well diffusion layer 9 and another n-type impurity diffusion layer 8 are provided adjacent to each other. In the bipolar n-type well diffusion layer 9, a p⁻ base diffusion layer 10 and a p⁺ base diffusion layer 11 are provided such that the p⁺ base diffusion layer 11 surrounds the p⁻ base diffusion layer 10. An n-type emitter diffusion layer 12 is provided in the p⁻ base diffusion layer 10.

A surface protection insulating layer 13 is provided on the entire surface of the n-type epitaxial layer 6 including the above-described layers of the photodiode region 30 and the bipolar transistor element region 40 as described above. Openings are formed in the surface protection insulating layer 13. The openings reach the n-type impurity diffusion layer 8 and the p-type separation diffusion layer 7 in the photodiode region 30, and the n-type impurity diffusion layer 8, the p⁺ base diffusion layer 11 and the n-type emitter diffusion layer 12 in the bipolar transistor element region 40. Each opening is filled with a wire (electrode) metal layer 14.

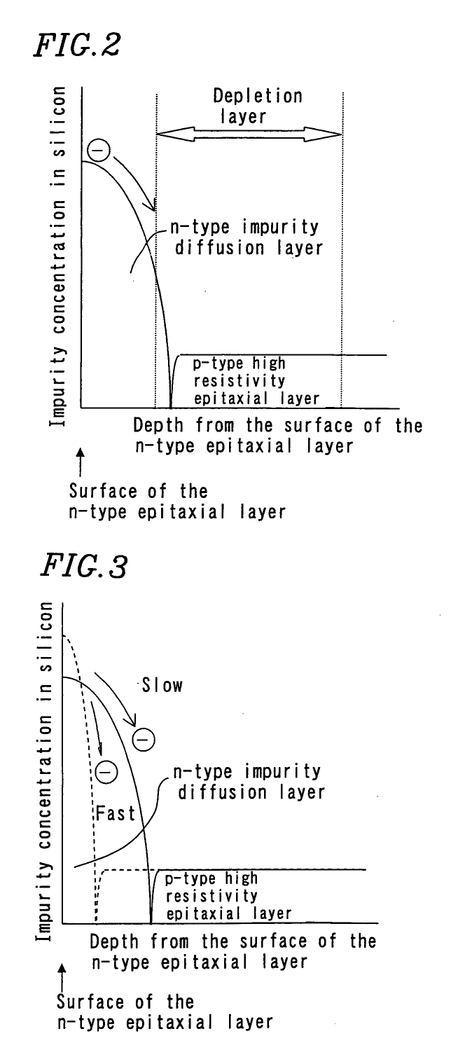

FIGS. 2 and 3 each schematically show the impurity concentration profile which illustrates the behavior of the optical carriers generated in the n-type impurity diffusion layer 8. In FIGS. 2 and 3, the vertical axis represents the impurity concentration in silicon, and the horizontal axis represents the depth from the surface of the photodiode region (from the surface of the n-type epitaxial layer 6).

As shown in FIG. 2, the optical carriers generated in the n-type impurity diffusion layer 8 move to the depletion layer by the potential gradient generated by the concentration gradient of the n-type impurity, and thus an optical current is generated. However, when the impurity concentration of the n-type impurity diffusion layer 8 is too high, the optical carriers are recombined and are extinguished before reaching the depletion layer, thus shortening the lifetime of the optical carriers. In this case, the optical carriers cannot contribute to generation of the optical current, and therefore the quantum efficiency of the photodiode region 30 is lowered.

Especially when the wavelength of light is shortened and thus the light absorption coefficient is increased, resulting in the light penetrating the semiconductor layer only to a lesser distance, the number of optical carriers generated in the n-type semiconductor diffusion layer 8 is increased. Therefore, when the n-type impurity diffusion layer 8 is too high, the quantum efficiency of the photodiode region 30 is significantly lowered.

In order to prevent the quantum efficiency from being lowered by recombination of optical carriers in the high concentration impurity diffusion layer and thus to optimize the impurity concentration profile, the following two methods are available.

Method 1 (FIG. 3): When the impurity concentration of the n-type impurity diffusion layer 8 is high, the n-type impurity diffusion layer 8 is formed to be shallow in order to make the gradient of the impurity concentration profile steeper such that the potential gradient is steeper. In this case, the speed of the optical carriers moving to the depletion layer is higher as compared to the case where the n-type impurity diffusion layer 8 is deeper. Thus, the optical carriers can move to the depletion layer without being recombined.

Method 2: When the n-type impurity diffusion layer 8 is deep, the impurity concentration is lowered so as to allow the optical carriers can move to the depletion layer without being recombined, thus extending the lifetime of the optical carriers.

According to method 1, since the n-type impurity diffusion layer 8 is shallow, the resistance is increased and thus the response speed is lowered. Therefore, the present invention adopts method 2 such that the photodiode region 30 has an increased response speed and an improved quantum efficiency.

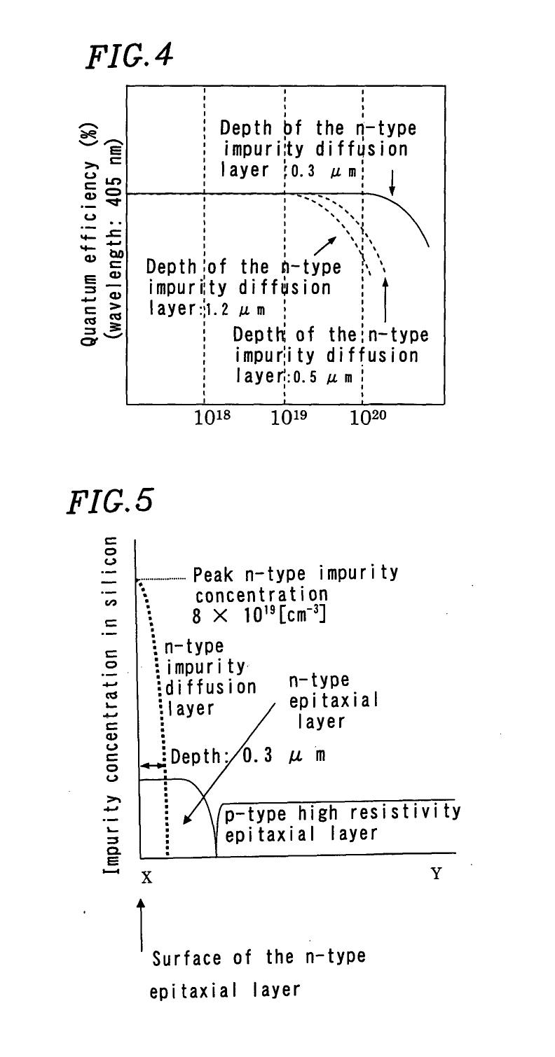

FIG. 4 is a graph illustrating the quantum efficiency with respect to light of a wavelength of 405 nm which is obtained while the diffusion depth and the impurity concentration of the n-type impurity diffusion layer 8 are varied. In FIG. 4, the vertical axis represents the quantum efficiency of the photodiode region 30 for light having a wavelength of about 405 nm. The horizontal axis represents the peak impurity concentration of the n-type impurity diffusion layer 8.

As shown in FIG. 4, even when light having a wavelength as short as 405 nm is used, the quantum efficiency is not lowered as long as the peak impurity concentration is less than about 1×10²⁰ cm⁻³ in the case where the depth of the n-type impurity diffusion layer 8 is about 0.3 μm from the surface of the epitaxial layer 6. Even when the n-type impurity diffusion layer 8 is shallower than about 0.3 μm, the quantum efficiency is not lowered as long as the impurity concentration is less than about 1×10²⁰ cm⁻³ since the potential gradient of the n-type impurity diffusion layer 8 is increased.

However, when the depth of the n-type impurity diffusion layer 8 is about 0.1 μm or less, the response speed of the photodiode region 30 is lowered since the cathode resistance influencing the response speed of the photodiode region 30 is raised. Therefore, the depth of the n-type impurity diffusion layer 8 is preferably greater than about 0.1 μm. In the light receiving element with a built-in circuit 20, the n-type impurity diffusion layer 8 tends to be deeper than about 0.1 μm since the n-type impurity diffusion layer 8 is exposed to high temperatures by heat treatment for forming a circuit.

FIG. 5 is a graph schematically illustrating an impurity concentration profile of the n-type impurity diffusion layer 8, the n-type epitaxial layer 6, and the p-type high resistivity epitaxial layer 3 along a cross-section of the light receiving element with a built-in circuit 20 taken along line X-Y of FIG. 1. In FIG. 5, the vertical axis represents the impurity concentration in silicon, and the horizontal axis represents the depth from the surface of the photodiode (from the surface of the n-type epitaxial layer 6).

In the first example, as shown in FIG. 5, the n-type impurity diffusion layer 8 has a peak impurity concentration of about 8×10¹⁹ cm⁻³ and extends to a depth of about 0.3 μm from the surface of the n-type epitaxial layer 6. Therefore, as shown in FIG. 4, the photodiode region 30 has a high sensitivity without the quantum efficiency being lowered. Since the depth of the n-type impurity diffusion layer 8 is about 0.3 μm, the cathode resistance influencing the response speed of the photodiode region 30 can be lowered so as to increase the response speed of the photodiode region 30.

In order to suppress light reflection at the surface of the photodiode region 30, a reflection prevention layer formed of an oxide layer (for example, SiO₂) and an Si₃N₄ layer may be provided at the surface of the light receiving section, i.e., the surface of the n-type epitaxial layer 6. This further improves the sensitivity of the photodiode region 30. In addition, the impurity concentration profile of the n-type impurity diffusion layer 8 is set so as to increase toward the surface of the n-type epitaxial layer 6. Thus, the quantum efficiency of the photodiode region 30 for light having a wavelength of 405 nm is approximately 100%, which is suitable for a blue laser optical disc apparatus.

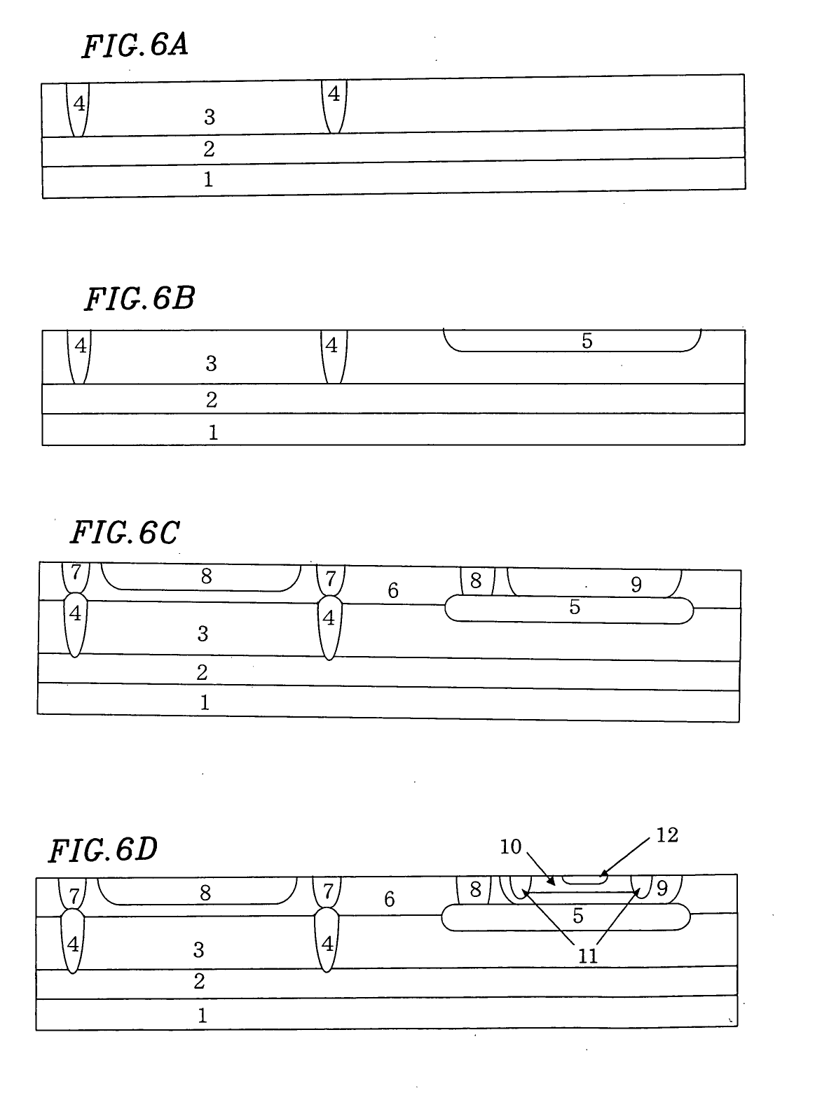

FIGS. 6A through 6D are cross-sectional views illustrating a method for producing the light receiving element with a built-in circuit 20 in the first example. Again, FIGS. 6A through 6D each show a part of the light receiving element with a built-in circuit 20 including one photodiode region and one bipolar transistor element region, for the sake of simplicity.

First, as shown in FIG. 6A, the p-type high concentration buried diffusion layer 2 is formed on the p-type semiconductor substrate 1. Then, the p-type high resistivity epitaxial layer 3 is formed on the p-type high concentration buried diffusion layer 2 by epitaxial growth. In the first example, the p-type high concentration buried diffusion layer 2 is formed on the p-type semiconductor substrate 1. Instead of the combination of the p-type semiconductor substrate 1 and the p-type high concentration buried diffusion layer 2, a p-type low resistivity substrate may be used.

Then, a p-type impurity layer is deposited on or a p-type impurity is ion-implanted into the p-type high resistivity epitaxial layer 3, and the p-type high resistivity epitaxial layer 3 is heat-treated. Thus, the p-type buried diffusion layers 4, reaching the interface between the p-type high resistivity epitaxial layer 3 and the p-type high concentration buried diffusion layer 2, are formed in the p-type high resistivity epitaxial layer 3.

As shown in FIG. 6B, the n-type buried diffusion layer 5 acting as a collector is formed on an area of the p-type high resistivity epitaxial layer 3 which will be included in the bipolar transistor element region 40.

Then, as shown in FIG. 6C, the n-type epitaxial layer 6 is formed on the entire surface of the p-type high resistivity epitaxial layer 3 so as to cover the p-type buried diffusion layers 4 and the n-type buried diffusion layer 5. The n-type epitaxial layer 6 is formed to a thickness of, for example, about 0.8 μm to 3.0 μm and to have a resistivity of about 1 Ωcm to 5 Ωcm. Instead of the n-type epitaxial layer 6, a p-type epitaxial layer maybe formed. The n-type epitaxial layer 6 may preferably have a resistivity of about 100 Ωcm or greater, in which case, the photodiode capacitance is lowered and the response speed of the photodiode region 30 is increased.

Then, the bipolar n-type well diffusion layer 9 is formed at a prescribed position of the n-type epitaxial layer 6 on the n-type buried diffusion layer 5. As described above, the n-type buried diffusion layer 5 is formed on a prescribed area of the p-type high resistivity epitaxial layer 3 which will be included in the bipolar transistor element region 40. The p-type impurity is ion-implanted from the surface of the n-type epitaxial layer 6, thereby forming the p-type separation diffusion layer 7 reaching the p-type buried diffusion layer 4.

An n-type impurity is ion-implanted from the surface of the n-type epitaxial layer 6, thereby forming the n-type impurity diffusion layers 8 in a prescribed area in the n-type epitaxial layer 6 which will be included in the photodiode region 30 and in a prescribed area on the n-type buried diffusion layer 5 (which will be included in the bipolar transistor element region 40). The n-type impurity diffusion layers 8 is formed to a depth of about 0.3 μm from the surface of the n-type epitaxial layer 6. The n-type impurity diffusion layers 8 are formed such that the peak impurity concentration is about 8×10¹⁹ cm⁻³. Since the n-type impurity diffusion layers 8 can be formed in the same step in the photodiode region 30 and the bipolar transistor element region 40, the number of steps can be reduced.

For forming the n-type impurity diffusion layers 8, it is preferable to perform the ion implantation via an oxide layer formed on the surface of the n-type epitaxial layer 6. In this way, the depth of the n-type impurity diffusion layers 8 is more easily controlled. In addition, the oxide layer may have the peak impurity concentration during the ion implantation. In this way, the n-type impurity diffusion layers 8 can more easily obtain an impurity concentration profile having an impurity concentration which increases toward the surface of the n-type epitaxial layer 6.

In order to diffuse the impurity to a depth of about 0.3 μm or less, arsenic ion is preferably used as the n-type impurity since this facilitates the control of the depth of the diffusion layer. Use of arsenic, which has a low diffusion coefficient, is especially preferable in the case of a light receiving element with a built-in circuit, since the temperature of the element becomes high due to the heat treatment for fabricating the circuit.

Then, as shown in FIG. 6D, the p⁻ base diffusion layer 10 and the p⁺ base diffusion layer 11 are formed in the bipolar n-type well diffusion layer 9, and then the n-type emitter diffusion layer 12 is formed in the p⁻ base diffusion layer 10. The characteristics of the bipolar transistor element region 40 are determined by the heat treatment following the formation of the n-type emitter diffusion layer 12.

Then, as shown in FIG. 1, the surface protection insulating layer 13 is formed on the entire surface of the n-type epitaxial layer 6 so as to cover the layers formed therein, and the openings are formed in the surface protection insulating layer 13. The openings are each filled with the wire (electrode) metal layer 14. Thus, the light receiving element with a built-in circuit 20 according to the first example is completed.

### EXAMPLE 2

A light receiving element with a built-in circuit according to a second example of the present invention is different from the light receiving element with a built-in circuit 20 shown in FIG. 1 in that the n-type impurity diffusion layer is formed to a depth of greater than about 0.3 μm but about 1.2 μm or less (for example, about 0.5 μm) from the surface of the n-type epitaxial layer 6 (FIG. 1). The n-type impurity diffusion layer has a peak impurity concentration of less than about 1×10¹⁹ cm⁻³ (for example, about 8×10¹⁸ cm⁻³). On the other points, the light receiving element with a built-in circuit according to the second example is identical with the light receiving element with a built-in circuit 20.

As shown in FIG. 4, where the depth of the n-type impurity diffusion layer is about 0.5 μm or about 1.2 μm, the quantum efficiency is reduced even when the peak impurity concentration is about 1×10²⁰ cm⁻³. The reason for this is that the gradient of the impurity concentration profile is less and thus the potential gradient is gentler than the case where the depth of the n-type impurity diffusion layer is about 0.3 μm. However, even where the depth of the n-type impurity diffusion layer is about 0.5 μm or about 1.2 μm, the quantum efficiency is not reduced as long as the peak impurity concentration is less than about 1×10¹⁹ cm⁻³.

When the n-type impurity diffusion layer is too deep, the impurity concentration profile shown in FIG. 2 is too gradual and thus the potential gradient is too gentle. This results in the diffusion speed of the optical carriers generated in the n-type impurity diffusion layer and moving to the depletion layer being lowered. Thus, the response speed of the photodiode region is lowered. For example, in an optical disc apparatus using light having a wavelength of 405 nm, when the depth of the n-type impurity diffusion layer is greater than about 1.2 μm from the surface of the n-type epitaxial layer 6, the response speed is insufficiently low. Therefore, the depth of the n-type impurity diffusion layer is preferably about 1.2 μm or less.

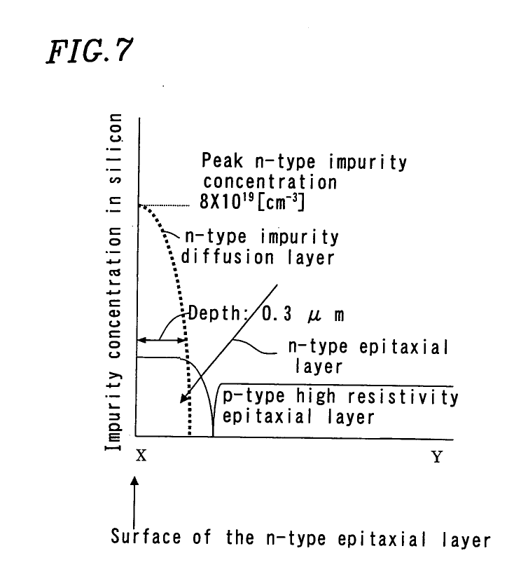

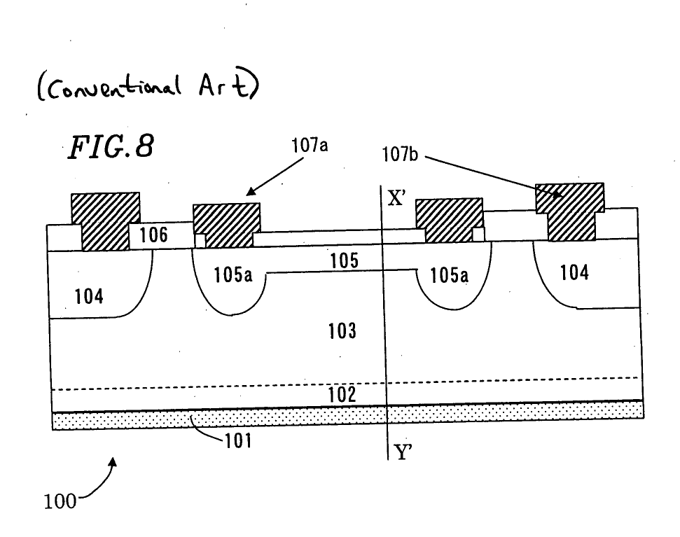

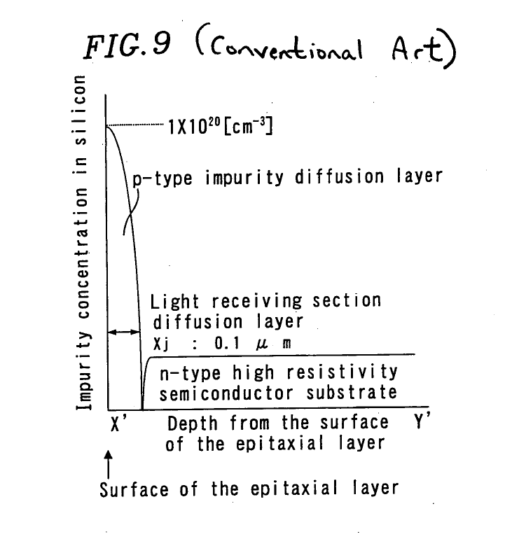

FIG. 7 is a graph schematically illustrating an impurity concentration profile of the n-type impurity diffusion layer, the n-type epitaxial layer 6, and the p-type high resistivity epitaxial layer 3 at a cross-section of the light receiving element with a built-in circuit of the light receiving element in the second example (corresponding to the cross-section taken along line X-Y of FIG. 1). In FIG. 7, the vertical axis represents the impurity concentration in silicon, and the horizontal axis represents the depth from the surface of the photodiode (from the surface of the n-type epitaxial layer 6).

In the second example, as shown in FIG. 7, the n-type impurity diffusion layer has a peak impurity concentration of about 8×10¹⁸ cm⁻³ and extends to a depth of about 0.5 μm from the surface of the n-type epitaxial layer 6. Therefore, as shown in FIG. 4, the photodiode region has a high sensitivity without the quantum efficiency being lowered. Since the n-type impurity diffusion layer in the second example is deeper than the n-type impurity diffusion layer 8 in the first example, the cathode resistance influencing the response speed of the photodiode region can be further lowered so as to increase the response speed of the photodiode region.

The present invention has been described by way of a light receiving element with a built-in circuit, which includes a light receiving element and a circuit element on one substrate. The present invention encompasses a structure including a light receiving element on a substrate without a circuit element. The present invention is also applicable to a structure in which the n-type impurity diffusion layer is provided in a p-type epitaxial layer, instead of in the n-type epitaxial layer.

The present invention is applicable to a structure in which the n-type layer or impurity and the p-type layer or impurity of the above examples are interchanged.

According to the present invention, an impurity diffusion layer is formed from the surface of the epitaxial layer to a depth in the range of greater than about 0.1 μm but about 0.3 μm or less. Owing to such a structure, the resistance of the light receiving element is lowered so as to increase the response speed of the light receiving element. The impurity diffusion layer has an impurity concentration of less than about 1×10²⁰ cm⁻³. Owing to such a structure, the lifetime of the optical carriers can be extended and the light receiving sensitivity of the light receiving element is improved even for light having a short wavelength of about 390 nm or longer but about 420 nm or shorter. The impurity diffusion layer may have a peak impurity concentration of about 1×10¹⁷ cm⁻³ or greater but about 1×10²⁰ cm⁻³ or less. Owing to such a structure, the light receiving element has an improved light receiving sensitivity without lowering the response speed of the light receiving element.

Also according to the present invention, an impurity diffusion layer is formed from the surface of the epitaxial layer to a depth in the range of greater than about 0.3 μm but about 1.2 μm or less. Owing to such a structure, the resistance of the light receiving element is lowered so as to increase the response speed of the light receiving element. The impurity diffusion layer has an impurity concentration of less than about 1×10¹⁹ cm⁻³. Owing to such a structure, the lifetime of the optical carriers can be extended and the light receiving sensitivity of the light receiving element is improved even for light having a short wavelength of about 390 nm or longer but about 420 nm or shorter. The impurity diffusion layer has a peak impurity concentration of about 1×10¹⁷ cm⁻³ or greater but about 1×10²⁰ cm⁻³ or less. Owing to such a structure, the light receiving element has an improved light receiving sensitivity without lowering the response speed.

In the case where the impurity is distributed in the impurity diffusion layer such that the impurity concentration increases toward the surface of the epitaxial layer, the potential gradient is prevented from dropping toward the surface of the epitaxial layer so as to suppress the recombination of optical carriers at the surface. Thus, the sensitivity of the light receiving element can be improved.

In the case where an oxide layer is formed on the surface of the epitaxial layer, and an impurity diffusion layer is formed by ion implantation via the oxide layer such that the peak of the impurity concentration is in the oxide layer, an impurity concentration profile having an impurity concentration which increases toward the surface of the epitaxial layer can be more easily formed.

Arsenic is preferably used as the impurity of the impurity diffusion layer since arsenic has a low diffusion coefficient and thus the depth of the impurity diffusion layer is easily controlled. Use of arsenic having a low diffusion coefficient is especially preferable in a light receiving element with a built-in circuit, where the light receiving element and the circuit element are provided on one substrate. The reason for this is that the temperature of the element becomes high due to the heat treatment for fabricating the circuit.

In the case where a reflective preventive layer formed of an oxide layer and an Si₃N₄ layer is provided on the surface of the epitaxial layer, the light can be prevented from being reflected at the surface and thus the sensitivity of the light receiving element can be improved.

In the case where a high resistivity epitaxial layer having a resistivity of about 100 Ωcm or higher is provided on a surface of the impurity diffusion layer closer to the substrate, the depletion layer is extended toward the high resistivity epitaxial layer when an inverse bias voltage is applied. Therefore, the capacitance of the light receiving element is reduced so as to realize a high speed response.

Various other modifications will be apparent to and can be readily made by those skilled in the art without departing from the scope and spirit of this invention. Accordingly, it is not intended that the scope of the claims appended hereto be limited to the description as set forth herein, but rather that the claims be broadly construed.

1. A light receiving element, comprising:
a substrate; and
an epitaxial layer provided on the substrate and containing an impurity diffusion layer extending from a surface of the epitaxial layer to a prescribed depth which does not reach a bottom surface of the epitaxial layer,
wherein:
the prescribed depth is about 0.3 μm or less, and
the impurity diffusion layer contains an impurity at a concentration of less than about 1×10²⁰ cm⁻³.

2. A light receiving element according to claim 1, wherein the substrate is of a first conductivity type, and the impurity is of a second conductivity type.

3. A light receiving element according to claim 2, wherein the epitaxial layer is of the first conductivity type.

4. A light receiving element according to claim 2, wherein the epitaxial layer is of the second conductivity type.

5. A light receiving element according to claim 1, wherein the impurity diffusion layer has a peak impurity concentration of about 1×10¹⁷ cm⁻³ or greater but less than about 1×10²⁰ cm⁻³.

6. A light receiving element according to claim 1, wherein the prescribed depth is greater than about 0.1 μm but about 0.3 μm or less.

7. A light receiving element according to claim 1, wherein the impurity diffusion layer has a concentration which increases toward the surface of the epitaxial layer.

8. A light receiving element according to claim 1, wherein the impurity is arsenic.

9. A light receiving element according to claim 2, wherein the first conductivity type is p-type, and the second conductivity type is n-type.

10. A light receiving element according to claim 1, further comprising a reflection prevention layer including an oxide layer and an Si₃N₄ layer and provided on a surface of the epitaxial layer.

11. A light receiving element according to claim 1, wherein the epitaxial layer is a high resistivity layer having a resistivity of about 100 Ωcm or greater.

12. A light receiving element according to claim 1, further comprising a high resistivity layer having a resistivity of about 100 Ωcm or greater provided between the substrate and the epitaxial layer.

13. A light receiving element according to claim 1, wherein the light receiving element performs opto-electronic conversion of light having a wavelength of about 390 nm or longer but about 420 nm or shorter.

14. A method for producing a light receiving element, comprising the steps of:
forming an epitaxial layer on a substrate; and
implanting an impurity into the epitaxial layer to a prescribed depth, thereby forming an impurity diffusion layer,
wherein:
the prescribed depth is about 0.3 μm or less, and
the impurity diffusion layer contains the impurity at a concentration of less than about 1×10²⁰ cm⁻³.

15. A method according to claim 14, wherein the step of forming the impurity diffusion layer includes the step of ion-implanting the impurity via an oxide layer formed on a surface of the epitaxial layer.

16. A light receiving element with a built-in circuit, comprising:
a light receiving element, including a substrate; and an epitaxial layer provided on the substrate and containing an impurity diffusion layer extending from a surface of the epitaxial layer to a prescribed depth which does not reach a bottom surface of the epitaxial layer,
wherein the prescribed depth is about 0.3 μm or less, and the impurity diffusion layer contains an impurity at a concentration of less than about 1×10²⁰ cm⁻³; and
a circuit element provided on the substrate.

17. A light receiving element, comprising:
a substrate; and
an epitaxial layer provided on the substrate and containing an impurity diffusion layer extending from a surface of the epitaxial layer to a prescribed depth,
wherein:
the epitaxial layer has a resistivity of from about 1 to 5 Ωcm,
the prescribed depth is greater than about 0.3 μm but about 1.2 μm or less, and
the impurity diffusion layer contains an impurity at a concentration of less than about 1×10¹⁹ cm⁻³.

18. A light receiving element according to claim 17, wherein the substrate is of a first conductivity type, and the impurity is of a second conductivity type.

19. A light receiving element according to claim 18, wherein the epitaxial layer is of the first conductivity type.

20. A light receiving element according to claim 18, wherein the epitaxial layer is of the second conductivity type.

21. A light receiving element according to claim 17, wherein the impurity diffusion layer has a peak impurity concentration of about 1×10¹⁷ cm⁻³ or greater but less than about 1×10¹⁹ cm⁻³.

22. A light receiving element according to claim 17, wherein the impurity diffusion layer has a concentration which increases toward the surface of the epitaxial layer.

23. A light receiving element according to claim 17, wherein the impurity is arsenic.

24. A light receiving element according to claim 18, wherein the first conductivity type is p-type, and the second conductivity type is n-type.

25. A light receiving element according to claim 17, further comprising a reflection prevention layer including an oxide layer and an Si₃N₄ layer and provided on a surface of the epitaxial layer.

26. (canceled)

27. A light receiving element according to claim 17, further comprising a high resistivity layer having a resistivity of about 100 Ωcm or greater provided between the substrate and the epitaxial layer.

28. A light receiving element according to claim 17, wherein the light receiving element performs opto-electronic conversion of light having a wavelength of about 390 nm or longer but about 420 nm or shorter.

29. A method for producing a light receiving element, comprising the steps of:
forming an epitaxial layer on a substrate; and
implanting an impurity into the epitaxial layer to a prescribed depth, thereby forming an impurity diffusion layer,
wherein:
the prescribed depth is greater than about 0.3 μm but about 1.2 μm or less, and
the impurity diffusion layer contains the impurity at a concentration of less than about 1×10¹⁹ cm⁻³.

30. A method according to claim 29, wherein the step of forming the impurity diffusion layer includes the step of ion-implanting the impurity via an oxide layer formed on a surface of the epitaxial layer.

31. A light receiving element with a built-in circuit, comprising:
a light receiving element, including a substrate; and an epitaxial layer provided on the substrate and containing an impurity diffusion layer extending from a surface of the epitaxial layer to a prescribed depth,
wherein the epitaxial layer has a resistivity of from about 1 to 5 Ωcm, the prescribed depth is greater than about 0.3 μm but about 1.2 μm or less, and the impurity diffusion layer contains an impurity at a concentration of less than about 1×10¹⁹ cm⁻³; and
a circuit element provided on the substrate.
